(19) United States
(12) Patent Application Publication
(10) Pub. No.: US 2016/0154079 A1
(43) Pub. Date: Jun. 2, 2016

(54) METHOD AND MAGNETIC RESONANCE APPARATUS FOR ACQUIRING A SENSITIVITY MAP FOR AT LEAST ONE LOCAL COIL IN A MAGNETIC RESONANCE SCANNER

(71) Applicant: Siemens Aktiengesellschaft, Muenchen (DE)

(72) Inventor: Vladimir Jellus, Kirchehrenbach (DE)

(73) Assignee: Siemens Aktiengesellschaft, Muenchen (DE)

(21) Appl. No.: 14/956,703

(22) Filed: Dec. 2, 2015

(30) Foreign Application Priority Data
Dec. 2, 2014 (DE) 102014224651.2

(51) Int. Cl. G01R 33/561; G01R 33/56

(52) U.S. Cl. CPC G01R 33/5611; G01R 33/5608

(57) ABSTRACT

In a method and magnetic resonance apparatus for acquiring a sensitivity map for at least one local coil in a magnetic resonance scanner, the extent of k-space to be sampled is divided into a first part located around the center of k-space, and a second part. First and the second magnetic resonance data sets are acquired with undersampling in at least one phase-coding direction in the second part, and are acquired globally in the first part. An accelerated parallel magnetic resonance imaging reconstruction technique is executed for the reconstruction of magnetic resonance data that are missing in the magnetic resonance raw data sets due to the undersampling, to produce a global data set defined by combining the first and the second magnetic resonance global data sets. Supplemented first and second magnetic resonance data sets are acquired by adding the reconstructed magnetic resonance data in the regions not covered in the undersampling. The sensitivity maps are acquired from the magnetic resonance data sets that have been supplemented in this way.

### BACKGROUND OF THE INVENTION

1. Field of the Invention

The invention concerns a method for acquiring a sensitivity map for at least one local coil in a magnetic resonance scanner that has a whole body coil, wherein, in the context of a prescan for the acquisition of a target object, a first three-dimensional magnetic resonance data set of the target object is acquired with the whole body coil and a second three-dimensional magnetic resonance data set is acquired with at least one local coil and the sensitivity map is acquired by comparing the first and the second magnetic resonance data set. In addition, the invention concerns a magnetic resonance apparatus for implementing such a method.

2. Description of the Prior Art

Many known magnetic resonance scanners, usually those that have a cylindrical patient receptacle, have a radio-frequency coil arrangement that is designed as a whole body coil and is frequently adjacent to a gradient coil arrangement. With such a whole body coil, which can be designed as a birdcage coil, for example, it is possible to receive signals in the entire image-generating region and therefore to carry out imaging. Due to the large distance of the whole body coil from the target object from which magnetic resonance data are to be acquired, such as an organ or an anatomical region of a patient, whole body coils deliver a limited image quality. This is why local coils are often used as receiving coils, which are in the direct vicinity of the target object or, in the case of endorectal coils, for example, can even be arranged inside the target object. With local coils, a clearly improved signal-to-noise ratio is possible, and moreover, when a number of local coils are used, it is also possible to carry out parallel imaging (PAT—parallel imaging technique). A problem related thereto is that with the whole body coil, it can be assumed that this coil has a consistent sensitivity over a wide area, in particular over the entire target object, which is not necessarily the case with local coils. The result of varying sensitivities, particularly when combining magnetic resonance signals received from different local coils, can be fluctuations in the intensity in magnetic resonance images.

To solve this problem, normalizing magnetic resonance data detected (acquired) with at least one local coil has been suggested, and strategies are known that use a priori know-how, preferably “prescan normalizing”. In this procedure, which has been known for quite some time, at least two magnetic resonance data sets are acquired, namely, a first magnetic resonance data set in which the whole body coil acts as a receiving coil, and at least one second magnetic resonance data set in which at least one local coil acts as a receiving coil. If it is now assumed that the whole body coil in the acquisition region, which is generally selected to be as large as possible, has a constant, consistent sensitivity, the result of a comparison of the first magnetic resonance data set and the second magnetic resonance data set is information about the local sensitivity of the at least one local coil that was used to acquire the second magnetic resonance data set, in other words a three-dimensional spatial sensitivity map. Here it is conceivable for an individual sensitivity map to be provided for each local coil, or also, however, to acquire a sensitivity map for an arrangement of a plurality of local coils. The inverse of the sensitivity shown by the sensitivity map is the correction factor that has to be applied to magnetic resonance images acquired later in order to compensate for and thus to correct the sensitivity fluctuations. Sensitivity maps can also be used in applications extending beyond such correction procedures, for example, in magnetic resonance spectroscopy with a plurality of local coils or when magnetic resonance data are combined in other contexts. It should be noted in addition, that for practical purposes, these prescan measurements are carried out before acquiring magnetic resonance images of the target object due to the influences of the target object on the sensitivity. In order to minimize the occurrence of movement artifacts, the method usually involves alternate measurement of each line in k-space with local coils and the whole body coil successively.

In order to reduce the duration of the scan, it is known practice to carry out an elliptical sampling of k-space that is to be scanned, gradient echo (GRE) sequences being commonly used as the magnetic resonance frequency. Although it has been known to acquire data in the phase coding directions for the three-dimensional sampling of k-space that is to be acquired, in the region of 32×32 lines for example, the resolution achieved thereby is no longer adequate for modern coils, in particular smaller local coils. Modern breast coils and endorectal are examples. Higher resolutions are therefore sought, for example, 64×64 k-space lines or 96×96 k-space lines, which clearly extends the duration of the scan, for example, by an amount in the range of 20 seconds for 64×64 k-space lines and even 30 to 40 seconds for 96×96 k-space lines. This is very disadvantageous since the overall duration of the scan is extended due to longer pre-scans.

### SUMMARY OF THE INVENTION

An object of the invention is to address the problem of accelerating measurements when acquiring sensitivity maps of local coils.

This object is achieved in accordance with the invention by a method of the type mentioned above, that has the following steps.

The extent of k-space to be sampled (filled with data) is divided into a first part located around the center of k-space, and a second part. First and the second magnetic resonance data sets are acquired with undersampling in at least one phase-coding direction in the second part, and are acquired globally in the first part. A reconstruction technique of the type used in accelerated parallel magnetic resonance imaging is executed for the reconstruction of magnetic resonance data that are missing in the magnetic resonance raw data sets due to the undersampling, to produce a global data set defined by combining the first and the second magnetic resonance global data sets. Supplemented first and second magnetic resonance data sets are acquired by adding the reconstructed magnetic resonance data in the regions not covered in the undersampling. The sensitivity maps are acquired from the magnetic resonance data sets that have been supplemented in this way.

Whole body coils usually have only one or two channels, through which they can be contacted; and likewise the number of local coils is sometimes not sufficient to carry out an accelerated parallel imaging in a sensible manner. In the method for accelerated parallel imaging, undersampling is likewise carried out in outer regions of k-space while global sampling is carried out in the center of k-space. By means of the global sampling in the center of k-space, in this case, that is in the first part, it is possible to calculate reconstruction parameters that allow the data that are missing due to the undersampling to be reconstructed in the second part. According to the invention, it has unexpectedly been found that for a global data set that has been acquired by combining the first magnetic resonance data set and the second magnetic resonance data set, it is still possible without impairment to carry out the data acquisition by undersampling of k-space in the second part at some distance from k-space center and to use the corresponding reconstruction technique of accelerated magnetic resonance imaging to obtain complete first and second magnetic resonance data sets, with which sensitivity maps of outstanding quality can be obtained. It is preferred in particular, if a multi-channel whole body coil and/or a number of local coils is/are used. Then a number of channels are available, which in total at least are sufficient to provide an adequate data base for reconstruction techniques for accelerated parallel magnetic resonance imaging. Of course, it is also conceivable to use single-channel whole body coils in the context of the present invention as an alternative to multichannel whole body coils.

In summary therefore, the invention proposes carrying out global sampling for both magnetic resonance data sets in the first part of k-space around the center of k-space but carrying out undersampling in one or two of the phase-coding directions in the region of the remaining k-space to be sampled. Both the magnetic resonance data sets acquired in this way are combined into a global data set, which contains lines thus scanned in k-space both by local coils and by the whole body coil. The central, first globally sampled part is used to locate reconstruction parameters (calibration coefficients) in order to reconstruct the missing magnetic resonance data in the second part, whereupon the global data set is again divided into the first magnetic resonance data set for the whole body coil and the second magnetic resonance data set for the at least one local coil. After this, the procedure can ensue as is known in the prior art in order to acquire the sensitivity map by, for example, voxel-based division in the spatial domain of the second magnetic resonance data set by the first magnetic resonance data set.

Studies have shown that by employing the inventive method, there is a clear reduction in the acquisition time for the prescan to acquire the sensitivity maps, for example, in a sampling of 64×64 k-space lines in the phase coding-direction from 20 seconds to 7 seconds, that is, by around a factor of 3. This does not entail any significant, detectable loss in the quality of the sensitivity maps, as test measurements have shown.

Because the same lines of k-space to be sampled are acquired for both magnetic resonance data sets, it is useful to implement alternating acquisition here as well, in order to minimize movement artifacts. The lines in k-space that are to be acquired can be scanned alternately for the first and the second magnetic resonance data sets, which means that there are successive switch-overs between the use of the whole body coil and the at least one local coil as a receiving coil.

Although it is conceivable for the first part of k-space that is to be sampled to be extremely small, such as three or only a few more directly adjacent k-space lines for example, it is preferable to encompass a greater number of k-space lines, preferably at least 12 k-space lines, within the first part of k-space that is to be sampled, in order to acquire as good as possible a reconstruction quality for the missing magnetic resonance data in the second part of k-space.

It is also particularly useful for the undersampling to ensue in both phase-coding directions and/or by the factor of two. In a preferred embodiment of the method according to the invention, only every other k-space line is sampled in both phase-coding directions. As a result, the reduction in the acquisition time for the prescan described in the aforementioned example is around a factor of 3. In particular, when larger numbers of local coils and/or channels of the whole body coil are provided, it is also possible to use higher undersampling factors, for example factors of three or higher, in order to further lower the acquisition time for the first and second magnetic resonance data sets, wherein a sufficiently precise reconstruction of the missing magnetic resonance data is possible.

Concepts that are basically known from the prior art may be used as an accelerated parallel imaging reconstruction techniques. Thus a GRAPPA technique or a CAIPIRINHA technique can be used as a reconstruction technique, for example. These two techniques are widely known in the prior art and each use the information from the first part in order to acquire reconstruction parameters that allow an improved interpolation of missing magnetic resonance data in the second part. As mentioned, it is therefore also possible in general for the reconstruction parameters that are to be taken into account in the reconstruction of the missing magnetic resonance data in the second part to be acquired from the globally sampled magnetic resonance data for the first part. Furthermore, it is particularly useful if more than two adjacent sampled k-space lines enter into the reconstruction of the missing magnetic resonance data.

GRAPPA stands for Generalized Autocalibrating Partially Parallel Acquisition, reference being made to the seminal article by Mark A. Griswold et al., “Generalized Autocalibrating Partially Parallel Acquisition (GRAPPA)”, Magnetic Resonance in Medicine 47: 1202-1210 (2002). The specific concept inherent in the GRAPPA Algorithm is causing more than one k-space line that has been acquired, in each case by different coils (in this case by the at least one local coil or by at least one channel of the whole body coil), to be input into the reconstruction of missing data, which ensues there with the aid of “calibration coefficients” used as reconstruction parameters that are acquired from the globally sampled magnetic resonance data for the first part. CAIPIRINHA stands for “Controlled Aliasing in Parallel Imaging Results in Higher Acceleration” and is described, for example, in the seminal article by Felix A. Breuer et al., “Controlled Aliasing in Parallel Imaging Results in Higher Acceleration (CAIPIRINHA) for Multi-Slice Imaging”, Magnetic Resonance in Medicine 53: 684-691 (2005). The CAIPIRINHA-Algorithm likewise uses the GRAPPA procedure.

It should be noted that the acquisition of the sensitivity map from the magnetic resonance data sets can include still further steps, such as the acquisition of regions from outside the target object that contain only noise, and the acquisition of a mask as well as the smoothing of data, as are basically already known from the prior art. Sensitivity maps can be acquired for individual local coils or even groups of local coils.

The sensitivity map can be used advantageously for correcting the intensity of a magnetic resonance image of the target object acquired after the pre-scan, as is already basically known from the prior art. In this case a conventional prescan normalization is achieved. Other areas of application in which the present invention can be used are of course conceivable, for example, in the context of magnetic resonance spectroscopy or in the context of an intensity-weighted combination of magnetic resonance data relating to different local coils.

The invention also concerns a magnetic resonance apparatus having a scanner that has a whole body coil therein, and a control computer that is designed to implement the method according to the invention.

The description relating to the method according to the invention applies as well to the magnetic resonance apparatus according to the invention, with which the aforementioned advantages can thus similarly be achieved. The control computer can include an acquisition unit that activates the remaining components of the magnetic resonance scanner in order to allow the acquisition of magnetic resonance data. In this case, this is the different, alternate acquisition of magnetic resonance data for the first and for the second magnetic resonance data set in the first and in the second part (where it is undersampled) of k-space that has been sampled. In a reconstruction processor, the reconstruction technique of accelerated parallel imaging, in particular using a GRAPPA algorithm, is used to reconstruct the magnetic resonance data that are missing due to undersampling. A splitting unit then divides the global data set again into the first and the second, now supplemented, magnetic resonance data sets, and a sensitivity map acquisition unit acquires the sensitivity map therefrom in a known manner.

### BRIEF DESCRIPTION OF THE DRAWINGS

FIG. 1 is a flowchart for an embodiment of the method according to the invention.

FIG. 2 shows how k-space is subdivided in accordance with the invention.

FIG. 3 schematically illustrates a magnetic resonance unit according to the invention.

### DESCRIPTION OF THE PREFERRED EMBODIMENTS

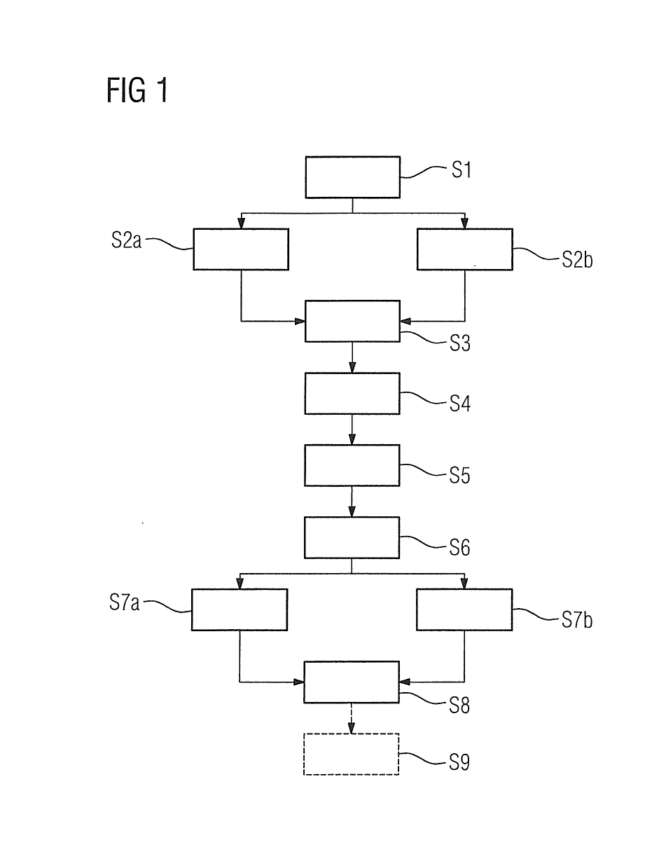

FIG. 1 is a flowchart if an embodiment of the method according to the invention. In the investigation of a target object, for example, of an organ of a patient, a sensitivity map of at least one local coil, in the example of three local coils, is meant to be acquired by a prescan. The method begins in step S1 with the actual measurement procedures. In steps S2a and S2b a first and a second magnetic resonance data set are acquired in parallel, a k-space line always being measured alternately by the whole body coil of the magnetic resonance unit, which in the present example can be selected via two channels, and by the three local coils, which therefore ultimately form three channels. In this way, the same k-space line is measured promptly, that is, in direct succession, both by the whole body coil and by the local coils, such that movement artifacts are kept to a minimum. A gradient echo sequence is used to acquire the magnetic resonance data.

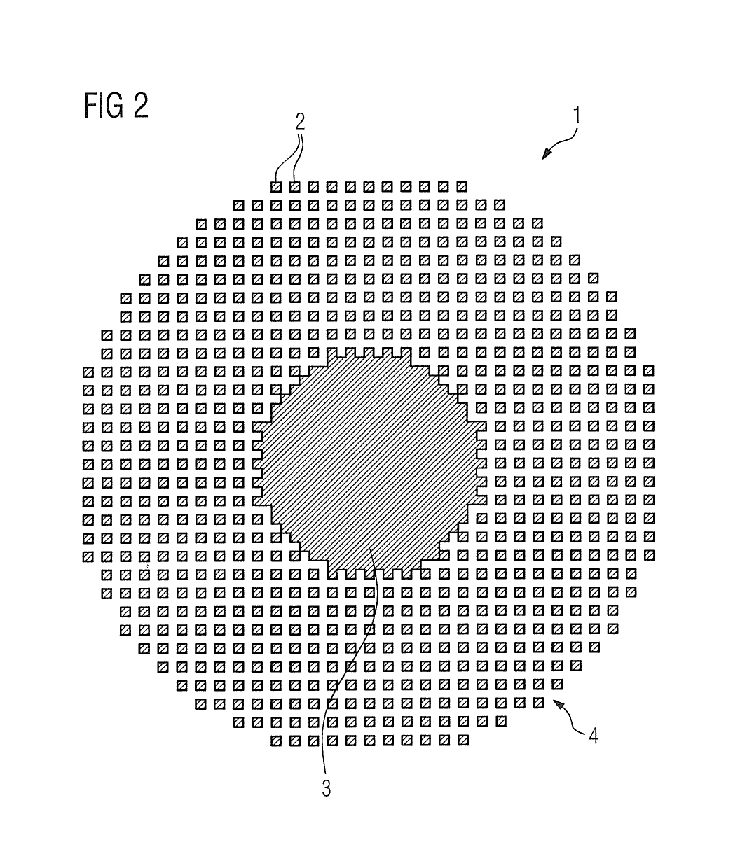

In steps S2a and S2b a partial undersampling of k-space ensues, as explained in further detail by FIG. 2, which shows in diagram form k-space 1 that is to be sampled in the plane formed by the two phase-coding directions; this means that k-space lines 2 proceed perpendicular to this plane (selection gradient). It can be seen that k-space 1 that is to be sampled is divided into a first, inner part 3 containing the center of k-space 1 and an outer (peripheral) part 4. In the acquisition procedure for steps S2a and S2b, filled in squares show k-space lines 2 that have actually been acquired, that means, the first part 3 is sampled globally, but the second portion 4 is acquired by undersampling, undersampling by a factor of 2 being selected in both phase-coding directions of the three-dimensional acquisition. This allows a reduction in scanning time in the present example from 20 second to 7 seconds, consequently by about a factor of 3.

The missing magnetic resonance data along lines 2 in k-space 1 that have not been sampled, which data were acquired for the calculation of the sensitivity map, are now to be reconstructed, such that, in a step S3, a global data set is formed by combining the first magnetic resonance data set, which was acquired in step S2a, and the second magnetic resonance data set, which was acquired in step S2b. Now it is evident that the global data set is based on five channels, that is, on three local coils and two channels of the whole body coil. The global data set can therefore be understood as a magnetic resonance data set generated in the context of parallel acquisition technology. Accordingly, it is intended that a GRAPPA algorithm should be used in the following steps as a reconstruction technique for the magnetic resonance data that are missing due to the undersampling.

Consequently, in step S4, the globally sampled magnetic resonance data for the first part, which are included in the global data set, are used as reconstruction parameters to determine the GRAPPA coefficients (calibration coefficients). In a step S5, the missing magnetic resonance data are then reconstructed, in a manner known in the prior art, in the second part 4 of k-space 1, taking into account adjacent k-space lines 2 that have been plotted for all the individual coils, thus both for the two channels of the whole body coil and the three local coils.

In a step S6, the global data set that has been supplemented with the reconstructed magnetic resonance data is then divided again into the part assigned to the whole body coil, i.e., first magnetic resonance data set, which has now also been supplemented accordingly, and the part assigned to the local coils, i.e., the second magnetic resonance data set, which has also been supplemented.

Therefore it is now possible with steps S7a or S7b to reconstruct three-dimensional images in a known manner from the first magnetic resonance data set and the second magnetic resonance data set, by transferring the magnetic resonance data for the first magnetic resonance data set and the second magnetic resonance data set into the spatial domain.

The result is consequently a spatially resolved three-dimensional image BC (x, y, z) of the first magnetic resonance data set and a spatially resolved three-dimensional image LC (x, y, z) of the second magnetic resonance data set, from which a sensitivity map for the local coils can be acquired as SC (x, y, z)/BC (x, y, z) in a step S8.

The sensitivity map acquired in this way can be used in various ways, for example, in a step S9 to correct fluctuations in the intensity in a magnetic resonance image of the target object subsequently acquired by the local coils, it then merely being necessary to multiply by the inverse of the sensitivity in the sensitivity map on a voxel-basis.

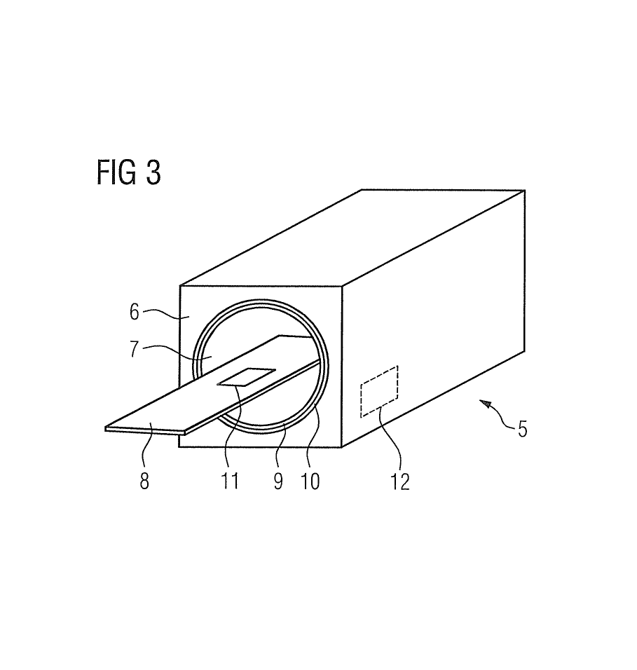

FIG. 3 schematically illustrates the principles of a magnetic resonance scanner 5 according to the invention. This shows, as is basically known, a basic field magnet unit 6, in which a patient recess 7 is formed, into which a patient bed 8 can be moved in order to obtain magnetic resonance raw data for transformation into an image of the patient. Surrounding the patient recess 7 is a radio-frequency coil arrangement formed as a whole body coil 9, and a gradient coil arrangement 10. Local coils 11 can additionally be arranged on the patient bed 8 or on and/or in a patient, only one back coil of these being shown here in diagram form, arranged on the patient bed 8.

The scanner 5 further has a control computer 12 that operates the magnetic resonance scanner 5 to acquire the raw magnetic resonance data. The control computer 12 is designed to carry out the method according to the invention. For this purpose the control computer 12 not only has an acquisition unit, with which the remaining components of the magnetic resonance scanner 5 can be activated to acquire the first and the second magnetic resonance data sets, as well as a reconstruction unit, in which the GRAPPA algorithm is implemented in order to reconstruct magnetic resonance data in the second part 4 of k-space 1. A data-splitting unit again splits the thus obtained, supplemented global data set into the first and the second magnetic resonance data sets, such that a sensitivity map can then be acquired in a sensitivity map acquisition unit, as described. The sensitivity map acquisition unit can also be designed to carry out further steps, for example, the acquisition of a mask that excludes the regions that show only noise and/or for smoothing the magnetic resonance data.

Although modifications and changes may be suggested by those skilled in the art, it is the intention of the inventor to embody within the patent warranted hereon all changes and modifications as reasonably and properly come within the scope of his contribution to the art.

I claim as my invention:

1. A method for acquiring a sensitivity map for a local coil in the magnetic resonance (MR) scanner, said MR scanner also comprising a whole body coil and a gradient coil system, said method comprising:
operating said MR scanner to acquire MR data from a target object situated in the MR scanner while activating a phase-coding gradient in a phase-coding direction with said gradient coils system;
via a processor in communication with said MR scanner, entering the acquired MR data into a memory representing k-space, wherein k-space comprises a plurality of points, organized dependent on said phase-coding direction, that are available for entering said acquired MR data thereat;
in said processor, dividing k-space in said memory to a first part that is situated around a center of k-space and that encompasses the center of k-space, and a second part;
operating said MR scanner to acquire said MR data from said target object as a three-dimensional first MR data set acquired with said whole body coil and a three-dimensional second MR data set acquired with said local coil, and entering each of said first and second MR data sets into k-space with said second part being undersampled in said phase-coding direction, so that not all of said available data points in said second part are filled with the acquired MR data, and with said first part being globally sampled so that all available data points in said first part are filled with the acquired MR data, thereby resulting in each of said first and second MR data sets in k-space having unfilled data points due to said undersampling;
in said processor, combining said first and second MR data sets in k-space to obtain a combined data set and applying an accelerated parallel magnetic resonance imaging reconstruction algorithm to said combined data set, to obtain a reconstructed MR data set;
in said processor, generating a supplemented first MR data set by adding reconstructed MR data from said reconstructed MR data set to fill said unfilled data points in said second region of said first MR data set that resulted from said undersampling, and generating a supplemented second MR data set by adding reconstructed MR data from said reconstructed MR data set to fill said unfilled data points in said second region of said second MR data set that resulted from said undersampling; and
in said processor, generating a sensitivity map for said local coil by comparing the supplemented first and second MR data sets, and making said sensitivity map available in electronic from from said processor.

2. A method as claimed in claim 1 comprising employing a multi-channel whole body coil as a whole body coil in said magnetic resonance scanner.

3. A method as claimed in claim 1 comprising employing a plurality of local coils in said magnetic resonance scanner, and determining said sensitivity map for each of said local coils.

4. A method as claimed in claim 1 wherein k-space comprises a plurality of k-space lines, and comprising acquiring said MR data that will be entered into a same k-space line in said first data set and said second data set alternatingly for the first data set and the second data set.

5. A method as claimed in claim 1 comprising defining said first part of k-space to encompass at least three k-space lines.

6. A method as claimed in claim 1 comprising defining said first part of k-space to encompass at least twelve k-space lines.

7. A method as claimed in claim 1 comprising operating said gradient coil arrangement to generate a further phase coding gradient in a further phase coding direction that is perpendicular to said phase coding direction, and undersampling said second part of k-space in both of said phase-coding directions.

8. A method as claimed in claim 1 comprising undersampling said first part of k-space by a factor of two.

9. A method as claimed in claim 1 comprising acquiring said first and second magnetic resonance data sets by operating said magnetic resonance scanner with a sequence selected from the group consisting of a GRAPPA sequence and a CAIPIRINHA sequence.

10. A method as claimed in claim 1 comprising using reconstruction parameters from the globally sampled magnetic resonance data in said first part of k-space when reconstructing the missing magnetic resonance data in said second part.

11. A method as claimed in claim 1 comprising using more than two adjacent lines in k-space for reconstructing said missing magnetic resonance data.

12. A method as claimed in claim 1 comprising, in said processor, using said sensitivity map to correct an intensity of magnetic resonance image data acquired by operating said magnetic resonance scanner after acquiring said first and second magnetic resonance data sets.

13. A magnetic resonance apparatus comprising:
a magnetic resonance scanner comprising a whole body coil and a local coil and a gradient coil arrangement;
a control computer configured to operate said MR scanner to acquire MR data from a target object situated in the MR scanner while activating a phase-coding gradient in a phase-coding direction with said gradient coils system;
a memory in communication with said control computer;
said control computer being configured to enter the acquired MR data into said memory, representing k-space, wherein k-space comprises a plurality of points, organized dependent on said phase-coding direction, that are available for entering said acquired MR data thereat;
said control computer being configured to divide k-space in said memory to a first part that is situated around a center of k-space and that encompasses the center of k-space, and a second part;
said control computer being configured to operate said MR scanner to acquire said MR data from said target object as a three-dimensional first MR data set acquired with said whole body coil and a three-dimensional second MR data set acquired with said local coil, and entering each of said first and second MR data sets into k-space with said second part being undersampled in said phase-coding direction, so that not all of said available data points in said second part are filled with the acquired MR data, and with said first part being globally sampled so that all available data points in said first part are filled with the acquired MR data, thereby resulting in each of said first and second MR data sets in k-space having unfilled data points due to said undersampling;
said control computer being configured to combine said first and second MR data sets in k-space to obtain a combined data set and apply an accelerated parallel magnetic resonance imaging reconstruction algorithm to said combined data set, to obtain a reconstructed MR data set;
said control computer being configured to generate a supplemented first MR data set by adding reconstructed MR data from said reconstructed MR data set to fill said unfilled data points in said second region of said first MR data set that resulted from said undersampling, and generating a supplemented second MR data set by adding reconstructed MR data from said reconstructed MR data set to fill said unfilled data points in said second region of said second MR data set that resulted from said undersampling; and
said control computer being configured to generate a sensitivity map for said local coil by comparing the supplemented first and second MR data sets, and making said sensitivity map available in electronic from from said control computer.
